(19) United States
(12) Patent Application Publication
(10) Pub. No.: US 2006/0067452 A1
(43) Pub. Date: Mar. 30, 2006

(54) Clock and data recovery circuit

(75) Inventors: Jianping Xu, Portland, OR (US); Fabrice Paillet, Hillsboro, OR (US); Peter Hazucha, Beaverton, OR (US); Tanay Karnik, Portland, OR (US)

Correspondence Address: FLESHNER & KIM, LLP, P.O. BOX 221200, CHANTILLY, VA, 20153, US

(73) Assignee: Intel Corporation

(21) Appl. No.: 10/948,697

(22) Filed: Sep. 24, 2004

(51) Int. Cl. H03D 3/24

(52) U.S. Cl. 375/376

(57) ABSTRACT

A clock and data recovery circuit is provided that includes a phase/frequency detector to receive input data and multiphase clock signals. The phase/frequency detector including a first set of flip-flop circuits each to sample the input data at one of the multiphase clock signals and each to output a sampled data, and a second set of flip-flop circuits to retime the sampled data based on a similar clock signal applied to each of the second set of flip-flop circuits.

### FIELD

Embodiments of the present invention may relate to logic circuits. More particularly, embodiments of the present invention may relate to clock and data recovery circuits.

### BACKGROUND

In many electronic systems, data may be transmitted or retrieved without any timing reference. For example, in optical communications, a stream of data may flow over a fiber without any accompanying clock signal. The receiving device may then be required to process this data synchronously. Therefore, the clock or timing information must be recovered from the data at the receiver using clock and data recovery (CDR) circuits. With the rapid growth of electrical and optical link capability, CDR circuits may require operating at high speeds such as tens of gigabits per second (Gbits/second).

### BRIEF DESCRIPTION OF THE DRAWINGS

The foregoing and a better understanding of the present invention may become apparent from the following detailed description of arrangements and example embodiments and the claims when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

The following represents brief descriptions of the drawings in which like reference numerals represent like elements and wherein:

FIG. 1 illustrates a CDR architecture using a full-rate PLL-based approach according to an example arrangement;

FIG. 2 illustrates a CDR architecture according to an example arrangement;

FIG. 3 illustrates a quarter-rate phase detector and other components of a CDR architecture according to an example arrangement;

FIG. 4A is a partial circuit diagram of a CDR architecture according to an example arrangement;

FIG. 4B is a timing diagram showing various signals from the CDR architecture shown in FIG. 4A;

FIG. 5 illustrates a CDR architecture according to an example embodiment of the present invention;

FIG. 6 is a circuit diagram of the CDR architecture of FIG. 5 according to an example embodiment of the present invention; and

FIG. 7 is a system level block diagram according to an example embodiment of the present invention.

### DETAILED DESCRIPTION

In the following detailed description, like reference numerals and characters may be used to designate identical, corresponding or similar components in differing FIG. drawings. Well-known power/ground connections to integrated circuits (ICs) and other components may not be shown within the figures for simplicity of illustration and discussion. Where specific details are set forth in order to describe example embodiments of the invention, it should be apparent to one skilled in the art that the invention can be practiced without these specific details.

Further, arrangements and embodiments may be described with respect to signal(s) and/or signal line(s). The identification of a signal or signal line may correspond to a single signal or a single signal line or may be a plurality of signals or signal lines. Additionally, the terminology of signal(s) and signal line(s) may be used interchangeably.

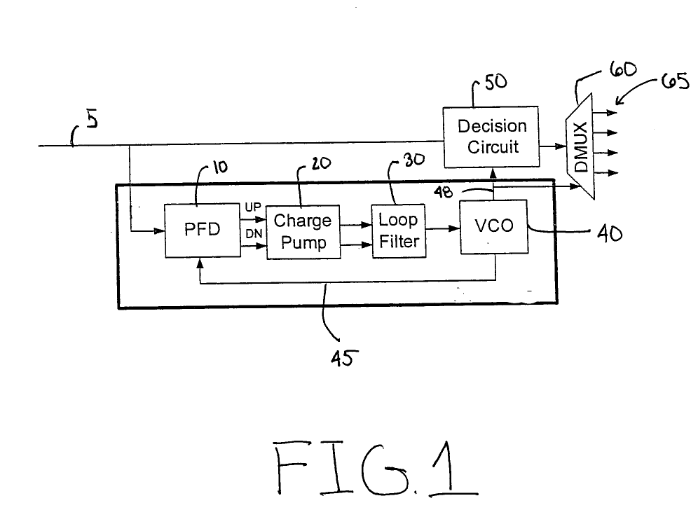

FIG. 1 illustrates a clock and data recovery (CDR) architecture using a full-rate PLL-based approach according to an example arrangement. Other arrangements are also possible. This type of CDR may synchronize random data to a clock generated by a voltage-controlled oscillator (VCO).

More specifically, FIG. 1 shows a phase/frequency detector (PFD) 10, a charge pump 20, a loop filter 30, a voltage controlled oscillator (VCO) 40, a decision circuit 50 and a demultiplexer (demux) 60. PFD 10 may detect phase and frequency differences (i.e., phase error and early-or-late information) between incoming data 5 and an output 45 of VCO 40. As one example, incoming data 5 may be non-return to zero (NRZ) data received at a rate of 20-30 Gbits/second. The phase error signals (i.e., UP and DOWN signals) from PFD 10 are fed through charge pump 20 and low pass filter 30 to create an appropriate voltage for VCO 40 to control a frequency of an output clock signal 48.

In this type of arrangement, decision circuit 50 may retime incoming data 5 and forward the retimed data to demultiplexer 60. Demultiplexer 60 separates a serial stream of data from decision circuit 50 into n parallel data streams 65 at 1/n frequency of clock signal 48 output from VCO 40.

The CDR approach shown in FIG. 1 may utilize a high-speed PFD 10 and a high-speed VCO 40 with low jitter at above 10 GHz. However, this may be difficult to accomplish in CMOS technology. Additional challenges may include requirements of high-speed flip-flops for data retiming and high-speed frequency dividers. The high frequency components are needed to generate the high frequency signals when utilizing a full rate architecture.

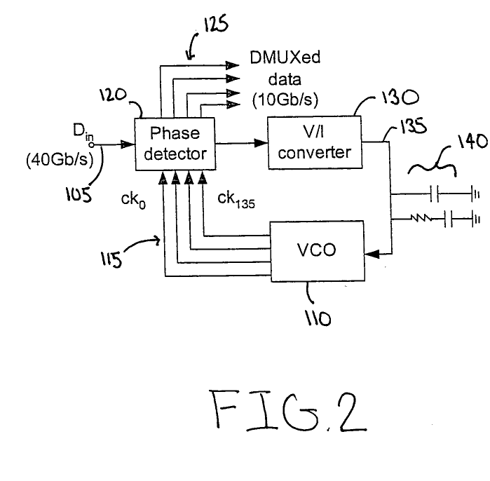

FIG. 2 illustrates a CDR architecture according to an example arrangement. Other arrangements are also possible. This arrangement may be considered a quarter rate architecture since four different phases are used to sample the input data. By utilizing the quarter rate architecture, higher frequency signals may be obtained without utilizing high frequency circuit components. More specifically, FIG. 2 shows a multiphase voltage controlled oscillator (VCO) 110, a quarter-rate phase detector (PD) 120, a voltage-to-current (V/I) converter 130, and a loop filter 140. PD 120 may sample input data (Din) 105 using multiphase clocks (e.g. differential ck0, ck45, ck90 and ck135) 115 generated by the VCO 110 in consecutive order so as to detect data edges and determine whether the clock is early or late. PD 120 may retime and demultiplex input data 105 into four output data streams 125. For example, input data 105 may be received at a rate of 40 Gbits/second and each of the four output data streams may be provided at a rate of 10 Gbits/second.

PD 120 may further output signals to V/I converter 130, which in turn provides signals across loop filter 140 to create an appropriate voltage for VCO 110 to control the frequency of multiphase clocks 115. In the absence of data transitions, the V/I converter 130 may not generate any output current, thereby leaving the control line of the VCO 110 undisturbed.

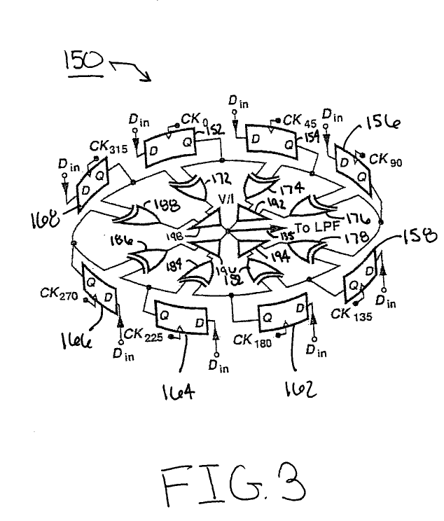

FIG. 3 illustrates a quarter-rate phase detector (PD) 150 and other components of a CDR architecture according to an example arrangement. Other arrangements are also possible. Quarter-rate phase detector 150 in FIG. 3 may correspond to PD 120 in FIG. 2. For ease of illustration, PD 150 of FIG. 3 will be described with respect to the various components and signals of the CDR architecture shown in FIG. 2.

PD 150 may include 8 flip-flop circuits 152, 154, 156, 158, 162, 164, 166 and 168 to strobe input data (Din) 105. Each of the flip-flops may receive one of the clock signals (ck0, ck 45, ck90, ck135, ck180, ck225, ck 270 and ck315) from VCO 110 in order to appropriately strobe input data 105. Outputs of the flip-flop circuits are provided to various ones of XOR gates 172, 174, 176, 178, 182, 184, 186 and 188. For example, outputs of flip-flop circuits 168 and 152 may be input to XOR gate 172. Outputs of flip-flop circuits 152 and 154 may be input to XOR gate 174. Outputs of flip-flop circuits 154 and 156 may be input to XOR gate 176 and outputs of flip-flop circuits 156 and 158 may be input to XOR gate 178. Likewise, outputs of flip-flop circuits 158 and 162 may be input to XOR gate 182. Outputs of flip-flop circuits 162 and 164 may be input to XOR gate 184 and outputs of flip-flop circuits 164 and 166 may be input to XOR gate 186. Finally, outputs of flip-flop circuits 166 and 168 may be input to XOR gate 188.

Each XOR gate 172, 174,176, 178,182, 184,186 and 188 may perform a logical XOR operation on the input signals and generate an output if the two inputs of the respective XOR gate are unequal (i.e., an edge occurs). The outputs of the XOR gates are provided to the V/I converter (shown as V/I elements 192, 194, 196 and 198 in FIG. 3) to perform the voltage to current conversion. More specifically, outputs of XOR gates 172 and 188 are provided to V/I element 198. Outputs of XOR gates 174 and 176 are provided to V/I element 192. Outputs of XOR gates 178 and 182 are provided to V/I element 194 and outputs of the XOR gates 184 and 186 are provided to V/I element 198. V/I converter 130 provides an output 135 to a low pass filter (such as low pass filter 140 shown in FIG. 2) and to VCO 110. As shown in FIG. 2, VCO 110 may accordingly adjust multiphase clocks 115.

As compared to the FIG. 1 architecture, the FIGS. 2 and 3 architectures may relax requirements of a high speed PD and a high speed VCO. In addition, the architectures may automatically retime and demultiplex data without using a decision circuit and/or a demultiplexer (such as decision circuit 50 and demultiplexer 60 shown in FIG. 1). However, in the FIGS. 2 and 3 architectures, PD 120 may use only one flip-flop circuit in each data sampling path. Inherently, the phase error cannot be obtained simultaneously. This may result in a jitter effect on the control of VCO 110.

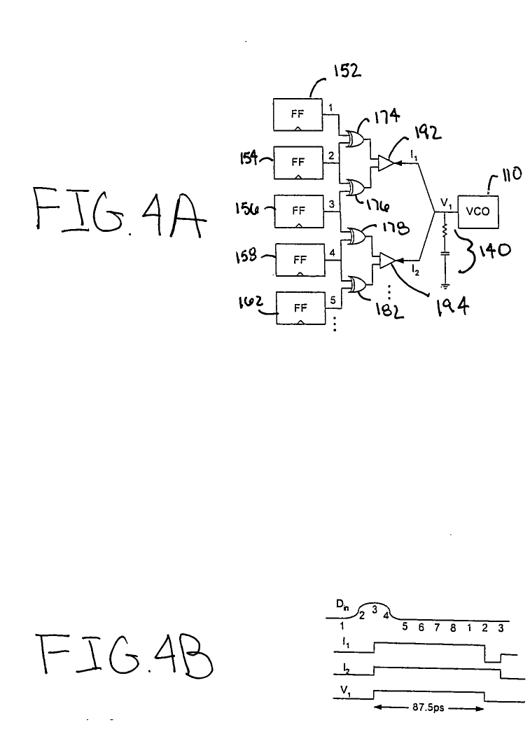

FIG. 4A is a partial circuit diagram of a CDR architecture according to an example arrangement. FIG. 4B is a timing diagram showing various signals from the CDR architecture shown in FIG. 4A. Other arrangements are also possible. For ease of illustration, FIG. 4A shows only 5 data sampling paths of the architecture although other numbers of data sampling paths, such as 8 data sampling paths, may be provided for this example CDR architecture. More specifically, FIG. 4A shows flip-flop circuits 152, 154, 156, 158 and 162. As discussed above with respect to FIG. 3, each of the flip-flop circuits may provide an output to one of the XOR gates 174, 176, 178 and 182. The XOR gates 174, 176, 178 and 182 perform a logical XOR operation on the input signals and provide outputs to V/I elements 192 and 194, which in turn perform a voltage to current conversion and provide an output across loop filter 140 to VCO 110.

In FIG. 4B, signal I₁ corresponds to the current output from V/I element 192 and signal I₂ corresponds to the current output from V/I element 194. These signals I₁ and I₂ may be combined to produce V₁ that passes through low pass filter 140 to VCO 110. Signal Din represents the signal input to flip-flop circuits 152, 154, 156, 158 and 162. Inherently, the timing of signals I₁ and I₂ causes jitter in VCO 110.

Embodiments of the present invention may utilize a half-rate phase detector and a half-rate voltage controlled oscillator so as to enable high-speed clock and data recovery without requiring a high-speed phase detector and voltage controlled oscillator as in disadvantageous arrangements. Embodiments of the present invention may also automatically retime and demultiplex data so that it does not require additional decision circuits and frequency dividers.

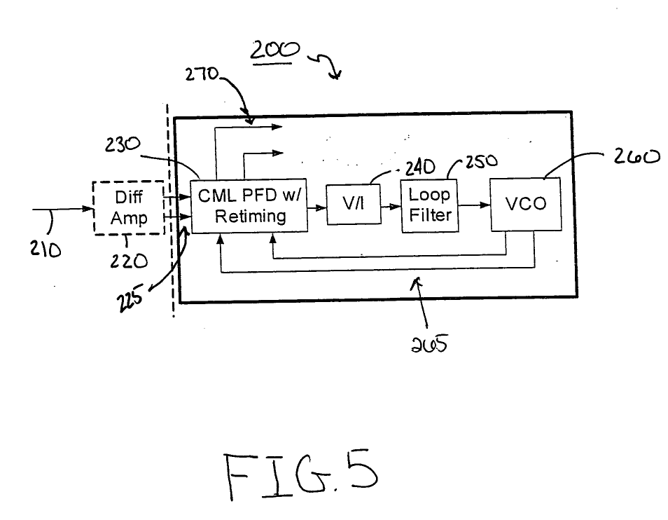

FIG. 5 illustrates a CDR architecture 200 according to an example embodiment of the present invention. Other arrangements and embodiments are also within the scope of the present invention. This CDR architecture may be called a half-rate CDR architecture since it utilizes four phases to sample the data. By utilizing the half rate architecture, higher frequency signals may be obtained without utilizing high frequency circuit components as in disadvantageous arrangements.

More specifically, FIG. 5 shows input data 210 inputs to a differential amplifier 220. For example, the input data 210 may be non-return to zero (NRZ) data input at a rate of 20-30 Gbits/second. Differential amplifier 220 may output data 225 to a current mode logic phase/frequency detector (CML PFD) 230 that includes a retiming circuit as will be described below. CML PFD 230 may sample input data 225 using multiphase clocks 265 generated by a VCO 260 and retime the sampled output data at a next cycle. Based on the retimed sample, data transition edges may be determined and used to determine whether the clocks are early or late. CML PFD 230 may retime and demultiplex input data 225 and provide demultiplexed output data 270. For example, the output data may be at a rate of 10-15 Gbits/second. Other input and output data rates are also within the scope of the present invention.

CML PFD 230 outputs signals representing data transitions to a voltage-to-current (V/I) converter 240, which provides signals across a loop filter 250 to control the multiphase clock outputs of the VCO 260.

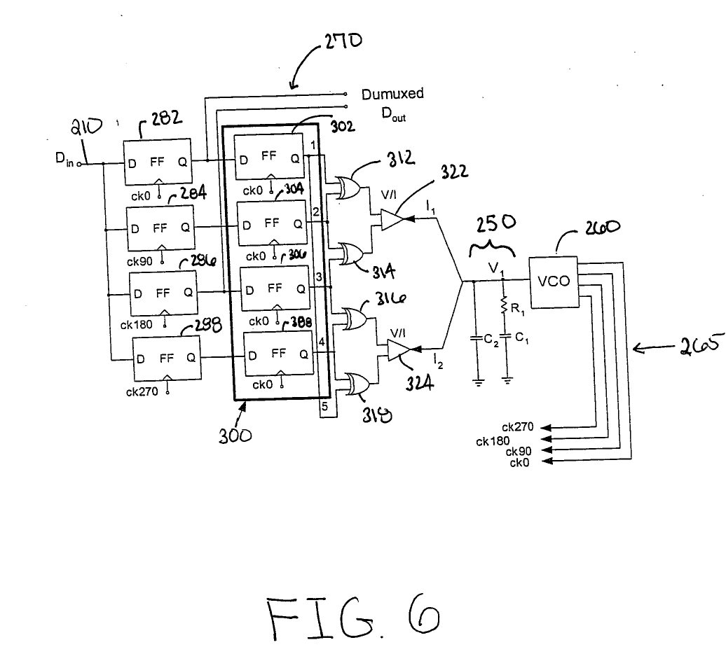

FIG. 6 is a circuit diagram of the CDR architecture of FIG. 5 according to an example embodiment of the present invention. Other arrangements and embodiments are also within the scope of the present invention. CML PFD 230 (of FIG. 5) may include flip-flop circuits 282, 284, 286 and 288 (also called a first stage of flip-flop circuits) and a retiming circuit 300 as shown in FIG. 6. Retiming circuit 300 may include flip-flop circuits 302, 304, 306 and 308 (also called a second stage of flip-flop circuits), each of which receives a similar clock signal ck0 so as to be similarly clocked. The use of retiming circuit 300 and the similar clock signal ck0 in the next clock cycle may remove (or reduce) jitter provided in disadvantageous arrangements.

Flip-flop circuits 302, 304, 306 and 308 of retiming circuit 300 may provide outputs (i.e., retimed sampled data) to XOR gates 312, 314, 316 and 318, which perform logical XOR operations and provide output signals to V/I elements 322 and 324 forming the V/I converter 240. The V/I elements 322 and 324 output signals that pass across loop filter 250 (shown in FIG. 6 as capacitors C₁, C₂ and resistor R.) to VCO 260. VCO 260 accordingly provides or adjusts clock signals ck0, ck90, ck180 and ck270 based on the signals from V/I converter 240 and across loop filter 250.

More specifically, flip-flop circuit 282 provides sampled data to flip-flop circuit 302 based on clock ck0. Flip-flop circuit 284 provides sampled data to flip-flop circuit 304 based on clock ck90. Still further, flip-flop circuit 286 provides sampled data to flip-flop circuit 306 based on clock ck180 and flip-flop circuit 288 provides sampled data to flip-flop circuit 308 based on clock ck270. Clock signals ck0, ck90, ck180 and ck270 correspond to multiphase clocks 265 generated by VCO 260. In other words, each of flip-flop circuits 282, 284, 286 and 288 samples the data at a different phase. Flip-flop circuits 282 and 286 clocked at ck0 and ck180 accordingly provide the demultiplexed output data 270. Demultiplexed output data 270 may correspond to half rate output signals since a half rate architecture is utilized.

As stated above, each of flip-flop circuits 302, 304, 306, 308 within retiming circuit 300 may be clocked at a same phase (or same clock signal) so as to reduce (or remove) jitter. Flip-flop circuits 302, 304, 306, 308 provide retimed sample data at a next cycle. The retimed sampled data output from flip-flop circuits 302 and 304 are input to XOR gate 312. The retimed sampled data output from flip-flop circuits 304 and 306 are input to XOR gate 314. Still further, the retimed sampled data output from flip-flop circuits 306 and 308 are input to XOR gate 316 and retimed sampled data output from the flip-flop circuits 308 and 302 are input to XOR gate 318. Outputs of XOR gates 312 and 314 are input to the V/I element 322 and outputs of XOR gates 316 and 318 are input to V/I element 324. V/I elements 322 and 324 perform a voltage to current conversion of the input signals and provide signals across loop filter 250 and VCO 260.

Operation of the CDR architecture will now be described with respect to features shown in FIGS. 5 and 6. Incoming data (Dᵢₙ) 210 may be sampled by flip-flop circuits 282, 284, 286 and 288 at clocks ck0, ck 90, ck180 and ck270, respectively, so as to provide sampled data to retiming circuit 300. The sampled data may be retimed by ck0 in the next cycle in retiming circuit 300. Based on the retimed sampled data, data transition edges can be detected by XOR gates 312, 314, 316 and 318. The outputs of XOR gates 312, 314, 316 and 318 may be sent to V/I converter 240 (shown as V/I elements 322 and 324 in FIG. 6). According to the polarity, early-or-late information may be provided across loop filter 250 to VCO 260. VCO 260 accordingly may adjust multiphase clocks 265 that are used to sample the incoming data. If there are no transitions, V/I converter 240 may not generate any current, thereby not producing any disturbance to VCO 260. Output (Dₒᵤₜ) 270 may be automatically retimed and demultiplexed if the phase is locked.

Since the data transitions can be detected simultaneously without staggering effect, this CDR architecture may produce less jitter than disadvantageous arrangements. To reject common mode noise, the circuits in this CDR architecture may be fully differential except for loop filter 250 and VCO 260. The half-rate CDR architecture may further relax latch design in phase detectors. Additionally, the retiming circuit may only utilize four additional flip-flop circuits in order to reduce the jitter of the half rate architecture. The phase detector may be implemented using current mode logic (CML) flip-flop circuits and CML XORs for speed requirements.

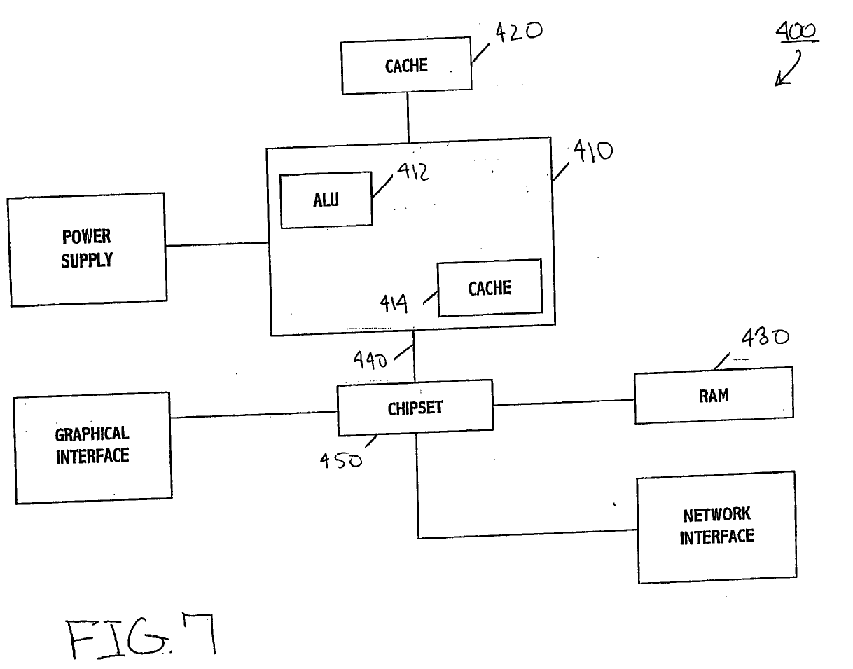

FIG. 7 is a system level block diagram of a system (such as a computer system 400) according to example embodiments of the present invention. Other embodiments and configurations are also within the scope of the present invention. More specifically, the computer system 400 may include a microprocessor 410 that may have many sub-blocks such as an arithmetic logic unit (ALU) 412 and an on-die cache 414. Microprocessor 410 may also communicate to other levels of cache, such as off-die cache 420. Higher memory hierarchy levels such as a system memory (or RAM) 430 may be accessed via a host bus 440 and a chip set 450. In addition, other off-die functional units such as a graphics accelerator and a network interface controller, to name just a few, may communicate with the microprocessor 410 via appropriate busses or ports.

Embodiments of the present invention utilizing a CDR architecture as discussed above may be provided within the system 400, such as within an input device of the electronic system so as to provide proper clock and data recovery. As one example, the CDR architecture shown in FIGS. 5 and 6 may be provided at the interface between the microprocessor 410 and the chipset 440. As another example, embodiments of the present invention (such as the CDR architecture shown in FIGS. 5 and 6, for example) may be provided as part of an electrical or optical interconnection between components. Data may be processed after the performance of the clock and data recovery and subsequent operations (such as output of data) may then occur.

Embodiments of the present invention may also be provided within any of a number of example electronic systems including electrical and/or optical interconnection and communication products. Examples of represented systems include computers (e.g., desktops, laptops, handhelds, servers, tablets, web appliances, routers, etc.), wireless communications devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 3) players, video games, watches, etc.), and the like.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A clock and data recovery circuit comprising:
a phase/frequency detector to receive incoming data and multiphase clock signals and to output data based on the incoming data and the multiphase clock signals, the phase/frequency detector including a first stage of circuits to sample the incoming data at a plurality of different phases based on the multiphase clock signals and to provide sampled data, the phase/frequency detector further including a second stage of circuits to receive the sampled data output from the first stage of circuits and to provide resampled data; and
a voltage controlled oscillator to provide the multiphase clock signals based on the resampled data.

2. The circuit of claim 1, wherein each of the second stage of circuits resamples the sampled data based on a similar clock signal.

3. The circuit of claim 1, wherein the first stage of circuits includes flip-flop circuits each clocked at a different clock phase, and the second stage of circuits includes flip-flop circuits each clocked at a same clock phase.

4. The circuit of claim 3, wherein the first stage of circuits includes four flip-flop circuits and the second stage of circuits includes four flip-flop circuits.

5. The circuit of claim 1, wherein the phase/frequency detector further includes a plurality of logic gates to receive the resampled data from the second stage of circuits and to detect data transition edges of the resampled signals.

6. The circuit of claim 5, wherein the plurality of logic gates comprise XOR logic gates to perform logical XOR operations.

7. The circuit of claim 5, further comprising a voltage to current converter and a loop filter, the voltage to current converter to receive outputs from the logic gates and to provide signals across the loop filter so as to control the voltage controlled oscillator.

8. The circuit of claim 1, wherein the phase/frequency detector comprises a half rate phase/frequency detector.

9. The circuit of claim 1, wherein the phase/frequency detector comprises a common mode logic (CML) phase/frequency detector.

10. The circuit of claim 1, wherein the second stage of circuits reduces jitter of the output data.

11. A clock and data recovery circuit comprising:
a detector to receive input data and multiphase clock signals and to provide output data signals based on the input data and the clock signals, the detector including a first set of flip-flop circuits each to sample the input data at one of the multiphase clock signals and each to provide sampled data, the detector further including a second set of flip-flop circuits to retime the sampled data based on a similar clock signal applied to each of the second set of flip-flop circuits;
a voltage to current converter coupled to the detector to provide output signals indicative of edge transitions; and
an oscillator to receive signals corresponding to the edge transitions and to output the multiphase clock signals to the detector.

12. The circuit of claim 11, wherein the first-set of flip-flop circuits includes four flip-flop circuits and the second set of flip-flop circuits includes four flip-flop circuits.

13. The circuit of claim 11, wherein the detector further includes a plurality of logic gates to receive the retimed sampled data from the second set of flip-flop circuits and to detect data transition edges of the retimed sampled data.

14. The circuit of claim 13, wherein the logic gates comprise XOR logic circuits to perform a logical XOR operation.

15. The circuit of claim 11, further comprising a loop filter, the voltage to current converter to receive outputs from the logic gates and to provide signals across the loop filter so as to control the oscillator.

16. The circuit of claim 11, wherein the detector comprises a half rate phase/frequency detector.

17. The circuit of claim 11, wherein the detector comprises a common mode logic phase/frequency detector.

18. The circuit of claim 11, wherein the second set of flip-flop circuits reduces jitter of the output data signals.

19. An electronic system comprising:
a device to provide data signals;
a processor to receive the data signals and to process the data, the processor including a clock and data recovery circuit having:
a voltage controlled oscillator to provide multiphase clock signals; and
a phase/frequency detector to receive incoming data and the multiphase clock signals from the voltage controlled oscillator and to output data based on the incoming data and the multiphase clock signals, the phase/frequency detector including a first stage of circuits to sample the incoming data at a plurality of different phases based on the multiphase clock signals and to provide sampled data, the phase/frequency detector further including a second stage of circuits to receive the sampled data output from the first stage of circuits and to provide resampled data.

20. The electronic system of claim 19, wherein each of the second stage of circuits resamples the sampled data based on a similar clock signal.

21. The electronic system of claim 19, wherein the first stage of circuits includes flip-flop circuits each clocked at a different phase, and the second stage of circuits includes flip-flop circuits each clocked at a same phase.

22. The electronic system of claim 21, wherein the first stage of circuits includes four flip-flop circuits and the second stage of circuits includes four flip-flop circuits.

23. The electronic system of claim 19, wherein the phase/frequency detector further includes a plurality of logic gates to receive resampled data from the second stage of circuits and to detect data transition edges of the resampled data.

24. The electronic system of claim 19, further comprising an output device to provide an output based on the data processed by the processor.
